(19) United States
(12) Patent Application Publication
(10) Pub. No.: US 2004/0099426 A1
(43) Pub. Date: May 27, 2004

(54) Flexible cable sleeve

(76) Inventors: Bohdan Bryl, Mississauga (CA); Leszek Wawrow, Toronto (CA)

Correspondence Address: MARKS & CLERK, 1075 NORTH SERVICE ROAD WEST, SUITE 203, OAKVILLE, ON, L6M 2G2, CA

(21) Appl. No.: 10/303,086

(22) Filed: Nov. 25, 2002

(51) Int. Cl. H05K 9/00

(52) U.S. Cl. 174/35 C

(57) ABSTRACT

Flexible cable sleeves are provided which have hook and loop fasteners along their length, and which are also provided with attachment elements so that they may be secured to supporting surfaces to keep bundles of wires and cables out of the way. Each flexible sleeve is made from a strip of material having a loop element on one side and a hook element on that side or the reverse side of the strip of material, and also having the attachment element typically on the side of a flexible material opposite to that where the loop element of the hook and loop fastener is located. The length and width of the flexible cable sleeve are determined by the purposes to which it will be put.

### FIELD OF THE INVENTION

This invention relates to cable sleeves, and particularly to flexible cable sleeves that are used in installations for such electronic devices as computers and facsimile machines, and in home entertainment installations. The invention particularly provides cable sleeves for organizing and maintaining bundles of wires and cables which may lead to any specific electronic device such as those referred to above.

### BACKGROUND OF THE INVENTION

Most homes and offices will have at least one or many installations of electronic devices, each of which has peripheral devices, power cables, wires leading to the peripheral devices, and so on. Any such installation therefore may have several or many wires and cables associated with the installation, usually hanging down from a shelf or shelves, desktop, and so on, and usually in an unsightly and potentially unsafe condition.

For example, a typical computer installation will have wires and cables leading to the computer, monitor, keyboard, speakers, printer, mouse, a scanner, possibly a network cable, and so on. As well, power cables are required for at least several such devices as the computer itself, the monitor, printer, etc. This leads to a proliferation of wires and cables, each of which serves a particular purpose, and each of which is important to the operation of the specific electronic device and its peripheral devices in that installation.

However, there always remains a risk that the cables and wires might accidentally be caught by a cleaner or other person who might just happen to be passing by; and this might lead to an inadvertent disconnection of a device or a peripheral therefor, or the dislodgment of such a device or peripheral from its resting place on its shelf or desktop.

Consequently, it has been well known in the past to use ties to bundle bunches of wires or cables together, at least so as to have all of the bundled wires or cables in the same place and not individually hanging down. Plastic ties are well known, and typically are of the type which may only be used once. That is, once they are put into place, if it is desired to remove or add a wire or cable to the bundle, it is necessary to cut off and discard the previous tie and replace it with another one. In a typical installation, the ties might be placed every 20 or 30 cm apart, so considerable amount of time and expenses are involved in placing the ties in the first instance and having to destroy the ties and replace them in the event that a new wire or cable is to be removed from or placed into the bundle.

Moreover, any such installation still leaves the bundled wires and cables hanging in space, where they are still possibly unsightly and unsafe. It is not possible to secure the bundled wires or cables in place against a supporting surface so as to be out of the way, and therefore in a less unsightly and safer place.

Yet another problem is that individual wires or cables may be required to leave or enter the bundle of wires and cables at any place along its length. This is due to the placement of individual devices or peripherals, and the requirement for providing power and/or data to any such device or peripheral. Thus, the number of wires or cables in a bundle may change from time to time along its length, and thus the effective diameter of the bundle may change from time to time.

All of these problems are overcome by the present invention, by which a flexible cable sleeve is provided which permits the bundling of wires and cables in a particular installation, and the securement of the bundle to a supporting surface which is out of the way.

Moreover, fire and shock hazards may be mitigated against by the present invention, since substantial portions of the length of power and data cables, and the like, may be covered by a flexible cable sleeve in keeping with the present invention, of which the cable sleeve may be fire resistant, waterproof, or both.

Still further, the present invention permits the removal or addition of wires or cables to the bundle of wires and cables which it is protecting, at any time. Indeed, the present invention provides a flexible cable sleeve which may be reused any number of times, and may be moved from one installation to another in certain circumstances.

### SUMMARY OF THE INVENTION

To that end, the present invention provides a flexible sleeve which is adapted to be removably secured to a supporting surface, for use to secure at least one wire in a location adjacent a supporting surface.

The flexible sleeve comprises a strip of material which has a length and a width, and which has first and second major surfaces.

The loop element of a hook and loop fastener is located at at least a first portion of one of the first and second major surfaces.

The hook element of a hook and loop fastener is located at at least a second portion of one of the first and second major surfaces.

There is at least one attachment element, which has first and second surfaces.

The first surface of the at least one attachment element is applied to one of the first and second major surfaces of the flexible sleeve.

The second surface of the at least one attachment element has an adhesive coating thereon, so as to removably secure the flexible sleeve to a supporting surface when in use. The second surface of the at least one attachment element has a release backing placed thereover, when the flexible sleeve is not in use.

The loop element of the hook and loop fastener may be at the first portion of the first major surface, and the hook element of the hook and loop fastener may be at the second portion which is located on the second major surface.

Otherwise, one of the first and second major surfaces of the flexible sleeve may have both the loop element and the hook element of the hook and loop fastener located thereon.

The flexible sleeve may have a plurality of attachment elements applied to one of its first and second major surfaces, and if so the attachment elements are spaced apart one from another.

Otherwise, the flexible sleeve may have a single attachment element applied to one of its first and second major surfaces and extending along the length thereof.

The at least one attachment element may be a double-sided adhesive tape.

Alternatively, the first surface of the at least one attachment element may further include the hook element of a hook and loop fastener, so as to removably secure that at least one attachment element to the respective one of the first and second major surfaces of the flexible sleeve.

The strip of material from which the flexible sleeve is made may be a fire retardant fabric material, a waterproof fabric material, or both.

In any embodiment of the present invention, the strip material of the flexible sleeve may be cut at a predetermined length from a continuous roll of material.

Also, in any embodiment of the present invention, the strip material of the flexible sleeve may be cut at a predetermined width from a sheeted material.

### BRIEF DESCRIPTION OF THE DRAWINGS:

The novel features which are believed to be characteristic of the present invention, as to its structure, organization, use and method of operation, together with further objectives and advantages thereof, will be better understood from the following drawings in which a presently preferred embodiment of the invention will now be illustrated by way of example. It is expressly understood, however, that the drawings are for the purpose of illustration and description only and are not intended as a definition of the limits of the invention. Embodiments of this invention will now be described by way of example in association with the accompanying drawings in which:

FIG. 1 is a perspective view of a first embodiment of the present invention;

FIG. 2 is an end view of the embodiment of FIG. 1;

FIG. 3a and FIG. 3b show alternative manners in which the embodiment of FIG. 1 may be rolled into a sleeve configuration;

FIG. 4 is a perspective view of a second embodiment of the present invention;

FIG. 5 is an end of view of the embodiment of FIG. 4;

FIG. 6a and FIG. 6b show alternative manners in which the embodiment of FIG. 2 may be placed into a sleeve configuration;

FIG. 7 is a perspective view of a third embodiment of the present invention;

FIG. 8 is an end view of the embodiment of FIG. 7;

FIG. 9 is a cross-sectional view along the lines 9-9 in FIG. 7;

FIG. 10 shows the manner in which the embodiment of FIG. 9 may be rolled into a sleeve configuration and secured to a supporting surface; and

FIG. 11 is a typical view showing the installation of flexible sleeves in keeping with the present invention.

### DETAILED DESCRIPTION OF THE PREFERRED EMBODIMENTS:

The novel features which are believed to be characteristic of the present invention, as to its structure, organization, use and method of operation, together with further objectives and advantages thereof, will be better understood from the following discussion.

Throughout the following discussion, and in the drawings, the designations “H” and “L” shall be understood to refer to the hook and loop elements which are commonly found in a hook and loop fastener system. Such hook and loop fastener systems are sold to the public very often in association with the trademark “VELCRO”.

It will also be understood throughout the following discussion that the reference to a flexible fabric will be not only limited to a single layer of fabric, but also to a multilayer construction by which a substrate fabric layer may be secured by known means such as sewing to another fabric layer. One or other of those fabric layers may comprise a hook element or a loop element of a hook and loop fastener, as will be more clearly explained hereafter.

Any embodiment of the present invention may comprise a fabric or several fabrics which provide the cable sleeve with fire resistant and/or waterproof characteristics.

Moreover, it will be understood that any embodiment of the present invention may be provided in any required or designated color. For example, flexible cable sleeve in keeping with the present invention which have designated sizes, both length and width, may be provided in different mutually distinctive colors. The color of any flexible cable sleeve in keeping with present invention may also indicate whether or not that cable sleeve has fire resistant and/or waterproof characteristics.

Referring first to FIG. 11, a typical installation is shown, where a plurality of cable sleeves 10 are employed to maintain cable bundles in a safe and out of sight condition.

Here, a typical installation comprises a computer 100, which has peripheral devices 102, 104, and 106, each of which has its own power and/or data cable or wire 110, 112, 114, 116, and so on. The computer and its peripheral devices sit on and are supported by a desk 120. As will be seen more clearly hereafter, the flexible cable sleeves 10 are easily applied to the bundle of wires and/or cables, and are easily secured to convenient supporting surfaces such as the underside of the top surface of the desk 120 or the inside surface of the leg 122 of the desk 120.

It will also be noted that wires such as 112 and 114 enter into the respective cable sleeve 10 at various intervals along its length.

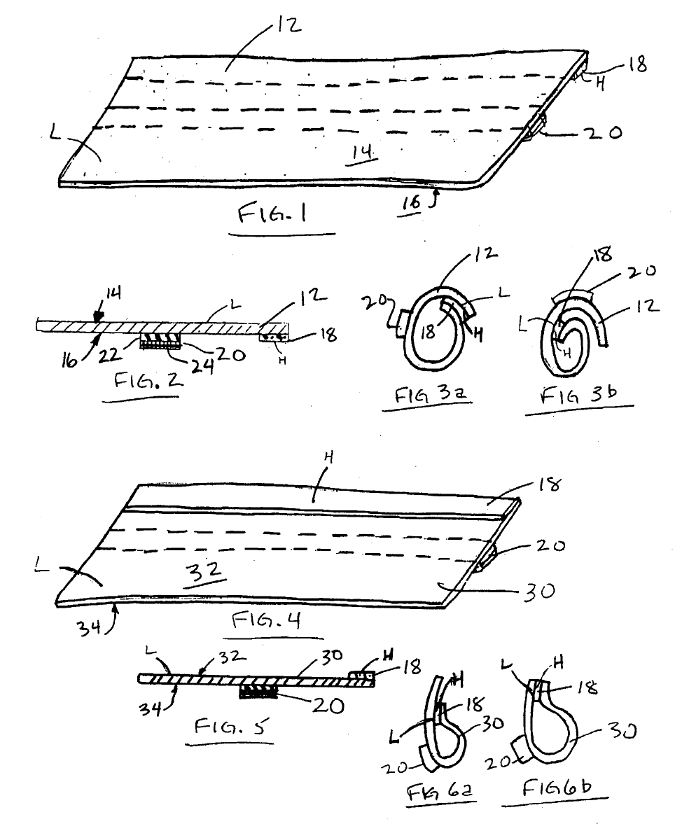

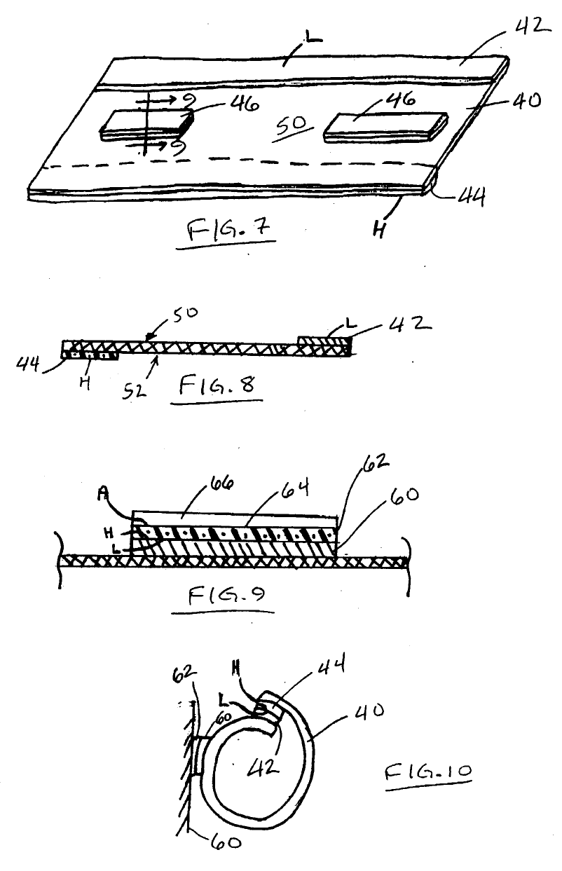

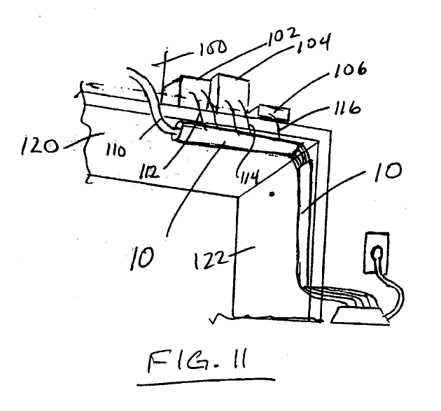

Various specific embodiments of cable sleeves in keeping with present invention will now be discussed in association with FIGS. 1 to 3; FIGS. 4 to 6; and FIGS. 7 to 10.

Turning first to FIG. 1, a strip of material 12 is shown, and it will be appreciated that the strip of material 12 has a length from one end to the other, and a width from one side to the other. It will be understood from the following discussion that neither the length nor the width of any flexible cable sleeve in keeping with present invention is specifically important in that both the length and the width of any fabric which comprises a specific flexible cable sleeve may vary from the length and width of another specific cable sleeve.

In this case, the material, or at least the upper surface thereof, which comprises the strip of material 12, may be entirely made of a material which can be employed as the loop element of a hook and loop fastener. Such material is available, for example, in association with the trademark “VELTEX”. The loop material may be secured such as by sewing to a suitable substrate material. The strip of material 12 has upper and lower surfaces, or first and second major surfaces 14 and 16. Secured to the lower major surface 16 there is a hook element 18, which extends along the length of the strip of material 12. Also secured to the lower major surface 16 is an attachment element 20, which also extends along the length of the strip of material 12.

Typically, the attachment element 20 comprises a double-sided adhesive tape 22 which has a release backing 24 placed thereover. It will be seen from FIGS. 3a and 3b that this embodiment of a sleeve element in keeping with the present invention may be rolled into several configurations. For example, in FIG. 3a, the hook element 18 is secured to the loop element 12 at its edge; whereas in FIG. 3b, the hook element 18 is secured to the loop element 12 somewhere along its width so as to form a smaller enclosure within the rolled flexible sleeve.

Referring once again to FIG. 11, the nature of the installation of the flexible sleeve 10 is now more clearly understood. Typically, the release backing 24 may first be removed from the attachment element 20, at least for the flexible sleeve which is to be employed as the upper sleeve as shown in the Figure, and the wires 110, 112, 114, etc., are put into place and then the sleeve is rolled in a manner such as that which is shown in FIG. 3a.

However, in the case of the lower sleeve, the wires and cables may first be gathered together, the sleeve 10 may be applied to them—typically from the bottom up—and then the sleeve 10 may be secured to the inner surface of the leg 122. However, it will be clearly understood that no matter in which order the sleeves are applied to the cables and wires, whether they are first secured to the supporting surface or are secured to the supporting surface after the wires and cables have been bundled, it is immaterial to the purposes and practice of the present invention.

Referring now to FIG. 4, a different embodiment to that which is shown in FIG. 1 is shown. Here, a strip of material 30 is chosen, and it is also such as to comprise the loop element of a hook and loop fastener, in the same manner as described above with respect to FIG. 1. The strip of material 30, once again, has first and second major surfaces—the upper and lower surfaces 32 and 34—but here the hook element 18 is secured to the upper surface 32. The attachment element 20 is secured to the lower surface 34 in the same manner as previously described.

However, because the hook element 18 is secured to the same surface as the loop element 30, the rolling of the sleeve is a bit different than that of the previous embodiment, as can be seen in FIGS. 6a and 6b. Nonetheless, the purposes and practice of the present invention are served. Once again, the enclosure within the rolled embodiment as shown in FIG. 6a is smaller than in the embodiment shown in FIG. 6b.

Referring now to FIG. 7, a further embodiment is shown wherein a specific substrate material 40 is employed, onto which a strip of loop element material 42 and a strip of hook element material 44 are secured in any conventional manner. Moreover, rather than the employment of a single strip of attachment element 20, as shown in FIGS. 1 and 4, a plurality of disconnected and spaced apart attachment elements 46 are shown in FIG. 7. Still further, an alternative structure for the attachment elements 46 is shown and described in FIG. 9.

In the embodiment of FIG. 7, the strip of loop material 42 is secured along one edge of the first major surface 50—the upper surface, as shown—and the strip of hook material 44 is secured to the lower surface 52. The manner in which the flexible sleeve of the embodiment of FIG. 7 is rolled, and is secured to a supporting surface 60, is clearly understood from FIG. 10.

The nature of the attachment elements 46, which might be substituted for the attachment element 20 in the embodiments of FIGS. 1 and 4, is more clearly understood with reference to FIG. 9. Here, a strip or a plurality of strips of loop element 60 are secured to the surface 50 of the fabric strip 40. Then, a strip of hook element 62 which has an upper (with reference to the orientation of FIG. 9) adhesive surface 64 and a removable release backing 66 placed thereover, is secured in typical hook and loop fashion to each respective strip of loop element 60. Of course, it will be understood that the particulars of the hook and loop strips 60 and 62 might be reversed; that is, the strip of loop element 60 might be substituted with a strip of hook element 62, and vice versa.

From all the above discussion, it will be clearly understood that the placement of a loop element or a hook element in a portion of the strip of material may mean that the entire surface of that strip of material is a loop element or a hook element, or only a portion of the surface comprises or has adhered or secured thereto a portion of a hook element or a loop element.

It will also be clearly understood that the length and width of any strip of material which is employed to comprise a flexible cable sleeve in keeping with the present invention is entirely one of choice. Quite typically, the length of the cable sleeve in keeping with the present invention may range from as little as 30 or 40 cm, up to as much as 200 cm. Also, the width of the flexible strips of material which comprise flexible cable sleeve in keeping with the present invention may range from 15 cm up to as much as 45 cm.

It follows that flexible sleeves in keeping with the present invention may be cut from sheeted material; or more particularly for embodiment such as those shown in FIGS. 1 and 4, in particular, the material may be provided in rolls which have a general appearance and particularly an end cross-section such as that shown in FIGS. 2 and 5, respectively. It also follows, of course, that the fire resistant and/or waterproof characteristics, or the color, of any flexible cable sleeve in keeping with present invention are matters of choice.

There has been described flexible cable sleeves, in respect of which several different embodiments have been taught. It will be clearly understood that the discussion above has been for purposes of explanation and clarity, and that flexible sleeves for purposes of maintaining bundles of wires and cables in neat and safe conditions, and in a manner such that they may be secured to a supporting surface, may be provided having specific structures and characteristics which are nonetheless in keeping with the teachings hereof, and as defined by the appended claims.

Other modifications and alterations may be used in the design and manufacture of the apparatus of the present invention without departing from the spirit and scope of the accompanying claims.

Throughout this specification and the claims which follow, unless the context requires otherwise, the word “comprise”, and variations such as “comprises” or “comprising”, will be understood to imply the inclusion of a stated integer or step or group of integers or steps but not to the exclusion of any other integer or step or group, of integers or steps.

What is claimed is:

1. A flexible sleeve which is adapted to be removably secured to a supporting surface, for use to secure at least one wire in a location adjacent a supporting surface, said flexible sleeve comprising:
a strip of material having a length and a width, and first and second major surfaces;
a loop element of a hook and loop fastener at at least a first portion of one of said first and second major surfaces;
a hook element of a hook and loop fastener at at least a second portion of one of said first and second major surfaces; and
at least one attachment element, having first and second surfaces;
wherein said first surface of said at least one attachment element is applied to one of said first and second major surfaces of said flexible sleeve; and
wherein said second surface of said at least one attachment element has an adhesive coating thereon so as to removably secure said flexible sleeve to a supporting surface when in use, and wherein said second surface of each of said at least one attachment element has a release backing placed thereover when said flexible sleeve is not in use.

2. The flexible sleeve of claim 1, wherein said loop element of said hook and loop fastener is at said first portion of said first major surface, and wherein said hook element of said hook and loop fastener is at said second portion of said second major surface.

3. The flexible sleeve of claim 1, wherein one of said first and second major surfaces has both said loop element and said hook element of said hook and loop fastener located thereon.

4. The flexible sleeve of claim 1, wherein said flexible sleeve has a plurality of attachment elements applied at one of said first and second major surfaces, and wherein said attachment elements are spaced apart from one another.

5. The flexible sleeve of claim 1, wherein said flexible sleeve has one attachment element applied at one of said first and second major surfaces, and said attachment element extends along the length of said flexible sleeve.

6. The flexible sleeve of claim 1, wherein said at least one attachment element is a double-sided adhesive tape.

7. The flexible sleeve of claim 1, wherein said first surface of said at least one attachment element further includes the hook element of a hook and loop fastener so as to removably secure said at least one attachment element to said respective one of said first and second major surfaces of said flexible sleeve.

8. The flexible sleeve of claim 1, wherein said strip of material is chosen from the group of materials consisting of fire retardant fabric materials, waterproof fabric materials, and combinations thereof.

9. The flexible sleeve of claim 1, wherein said strip of material is cut at a pre-determined length from a continuous roll of material.

10. The flexible sleeve of claim 1, wherein said strip of material is cut at a pre-determined width from a sheeted material.
